(19) United States
(12) Patent Application Publication
(10) Pub. No.: US 2025/0070515 A1
(43) Pub. Date: Feb. 27, 2025

(54) SHIELD MEMBER

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Mikio SATO, Mie (JP)

(21) Appl. No.: 18/720,825

(22) PCT Filed: Dec. 16, 2022
(86) PCT No.: PCT/JP2022/046541

§ 371 Date: Jun. 17, 2024

(30) Foreign Application Priority Data
Dec. 27, 2021 (JP) 2021-213261

(51) Int. Cl. H01R 13/6581; C23C 28/02; H01R 13/6598; H05K 9/00

(52) U.S. Cl. CPC H01R 13/6581; C23C 28/021; C23C 28/023; H01R 13/6598; H05K 9/0088

(57) ABSTRACT

A shield member includes a die-cast member and a plating layer provided on a surface of the die-cast member. The die-cast member contains zinc. The plating layer includes a third layer provided in an outermost surface of the plating layer. The third layer is made of pure tin. A thickness of the third layer is less than 5 μm.

### TECHNICAL FIELD

The present disclosure relates to a shield member.

This application claims a priority based on Japanese Patent Application No. 2021-213261 filed with the Japan Patent Office on Dec. 27, 2021, the contents of which are hereby incorporated by reference.

### BACKGROUND

Patent Document 1 discloses a shield cage provided with a die-cast metal section. The die-cast metal section is made of zinc alloy and plated with a layer of copper, nickel and tin.

### PRIOR ART DOCUMENT

### Patent Document

Patent Document 1: JP 2007-527095 A

### SUMMARY OF THE INVENTION

The present disclosure is directed to a shield member with a die-cast member and a plating layer provided on a surface of the die-cast member, the die-cast member containing zinc, the plating layer including a third layer provided in an outermost surface of the plating layer, the third layer being made of pure tin, and a thickness of the third layer being less than 5 μm.

### BRIEF DESCRIPTION OF THE DRAWINGS

FIG. 1 is a schematic section showing a shield member of a first embodiment.

FIG. 2 is a schematic section showing an example of a shield member of a second embodiment.

FIG. 3 is a schematic section showing another example of the shield member of the second embodiment.

FIG. 4 is a schematic section showing a shield member of a third embodiment.

FIG. 5 is a schematic section showing an example of a shield member of a fourth embodiment.

FIG. 6 is a schematic section showing another example of the shield member of the fourth embodiment.

### DETAILED DESCRIPTION TO EXECUTE THE INVENTION

### Technical Problem

If a plating layer is formed on a die-cast member containing zinc, the plating layer is possibly swollen or peeled under a high temperature.

One object of the present disclosure is to provide a shield member in which a plating layer provided on a die-cast member containing zinc is hardly swollen or peeled even under a high temperature.

### Effect of Invention

In a shield member of the present disclosure, a plating layer provided on a die-cast member containing zinc is hardly swollen or peeled even under a high temperature.

### DESCRIPTION OF EMBODIMENTS OF PRESENT DISCLOSURE

First, embodiments of the present disclosure are listed and described.

(1) A shield member according to a first embodiment of the present disclosure is provided with a die-cast member and a plating layer provided on a surface of the die-cast member, the die-cast member containing zinc, the plating layer including a third layer provided in an outermost surface of the plating layer, the third layer being made of pure tin, and a thickness of the third layer being less than 5 μm.

A state of the shield member of (1) is a state before being exposed under a high temperature. In the shield member of the present disclosure, the plating layer is hardly swollen or peeled even under a high temperature since the thickness of the third layer satisfies a specific range.

(2) In the shield member of the above (1) of the present disclosure, the plating layer may include at least one of a first layer and a second layer, the first layer, the second layer and the third layer may be provided in this order from a position near the die-cast member, the first layer may be made of pure copper, and the second layer may be made of pure nickel.

In the shield member of (2), the electrical conductivity of the shield member is easily satisfactorily ensured. In the shield member of (2), solder wettability is easily satisfactorily ensured.

(3) In the shield member of the above (2) of the present disclosure, the plating layer may include the second layer and a fourth layer provided between the second layer and the third layer, and the fourth layer may be made of pure copper.

If the second and third layers are in contact, nickel in the second layer and tin in the third layer are easily alloyed under a high temperature. When being alloyed, the third layer made of pure tin becomes thinner. In the shield member of (3), the alloying of nickel in the second layer and tin in the third layer can be suppressed by providing the fourth layer between the second and third layers. Under a high temperature, copper in the fourth layer and tin in the third layer are easily alloyed, but copper is less alloyed with tin than nickel. Thus, by providing the fourth layer between the second and third layers, it is more easily suppressed that the third layer becomes thinner under a high temperature as compared to the case where the second and third layers are in contact.

(4) In the shield member of any one of the above (1) to (3) of the present disclosure, a thickness of the third layer may be 1 μm or more.

In the shield member of (4), the electrical conductivity of the shield member is easily satisfactorily ensured. In the shield member of (4), solder wettability is easily satisfactorily ensured.

(5) A shield member according to a second embodiment of the present disclosure is provided with a die-cast member and a plating layer provided on a surface of the die-cast member, the die-cast member containing zinc, the plating layer including at least one of a first layer, a second layer and a third layer, the first layer, the second layer and the third layer being provided in this order from a position near the die-cast member, the first layer containing copper, the second layer containing nickel, the third layer being made of pure tin, and a thickness of the third layer being 0 μm or more and less than 3 μm.

A state of the shield member of (5) is a state after being exposed under a high temperature. In the shield member of the present disclosure, the plating layer is hardly swollen or peeled even under a high temperature since the thickness of the third layer satisfies the specific range.

(6) In the shield member of the above (5), the plating layer may include the first layer and the second layer, the first layer may include a first alloy layer containing zinc and copper and a first pure metal layer made of pure copper, the first alloy layer may be provided right on the die-cast member, the first pure metal layer may be provided right on the first alloy layer, the second layer may include a second alloy layer containing tin and nickel and a second pure metal layer made of pure nickel, the second pure metal layer may be provided right on the first pure metal layer, and the second alloy layer may be provided right on the second pure metal layer.

The shield member of (6) is configured by exposing the shield member of (2) under a high temperature.

If the die-cast member and the first layer are in contact, zinc in the die-cast member and copper in the first layer are possibly alloyed under a high temperature. By alloying zinc and copper, the first alloy layer is formed as a part of the first layer right on the die-cast member. When zinc and copper are alloyed, voids are possibly created between the die-cast member and the first alloy layer. The plating layer may be peeled by these voids. Since the thickness of the third layer satisfies the specific range, voids are hardly created and the plating layer is hardly peeled even if the first alloy layer is formed under a high temperature.

If the second and third layers are in contact, nickel in the second layer and tin in the third layer are possibly alloyed under a high temperature. By alloying nickel and tin, the second alloy layer is formed as a part of the second layer. When nickel and tin are alloyed, tin is possibly melted by a high temperature. Tin may agglomerate and be solidified by this melting of tin. Since the thickness of the third layer satisfies the specific range, it is suppressed that tin in the third layer is melted, agglomerates and is solidified under a high temperature, and the plating layer is hardly peeled. If the shield member of (2) is exposed under a high temperature, the thickness of the third layer may become 0 μm.

(7) In the shield member of the above (5), the plating layer may include the first layer and the second layer, the first layer may be an alloy layer containing zinc and copper, the second layer may include a second alloy layer containing tin and nickel and a second pure metal layer made of pure nickel, the second pure metal layer may be provided right on the first layer, and the second alloy layer may be provided right on the second pure metal layer.

The shield member of (7) exhibits effects similar to those of the shield member of (6). In the shield member of (7), the first alloy layer is formed as the first layer right on the die-cast member.

(8) In the shield member of the above (5), the plating layer may include the first layer, the second layer and a fourth layer provided right on the second layer, the first layer may include a first alloy layer containing zinc and copper and a first pure metal layer made of pure copper, the first alloy layer may be provided right on the die-cast member, the first pure metal layer may be provided right on the first alloy layer, the second layer may include a pure metal layer made of pure nickel, and the fourth layer may be an alloy layer containing tin and copper.

The shield member of (8) is configured by exposing the shield member of (3) under a high temperature.

If the die-cast member and the first layer are in contact, zinc in the die-cast member and copper in the first layer are possibly alloyed under a high temperature. By alloying zinc and copper, the first alloy layer is formed as a part of the first layer right on the die-cast member. When zinc and copper are alloyed, voids are possibly created between the die-cast member and the first alloy layer. The plating layer may be peeled by these voids. Since the thickness of the third layer satisfies the specific range, voids are hardly created and the plating layer is hardly peeled even if the first alloy layer is formed under a high temperature.

By providing the fourth layer between the second and third layers, it can be suppressed that nickel in the second layer and tin in the third layer are alloyed under a high temperature. Nickel and tin are easily alloyed. When being alloyed, the third layer becomes thinner. By providing the fourth layer between the second and third layers, it is more easily suppressed that the third layer becomes thinner under a high temperature as compared to the case where the second and third layers are in contact. Copper in the fourth layer and tin in the third layer are alloyed under a high temperature. When copper and tin are alloyed, tin is possibly melted by a high temperature. By this melting of tin, tin may agglomerate and be solidified. Since the thickness of the third layer satisfies the specific range, it is suppressed that tin in the third layer is melted, agglomerates and is solidified under a high temperature, and the plating layer is hardly peeled. If the shield member of (3) is exposed under a high temperature, the thickness of the third layer may become 0 μm.

(9) In the shield member of the above (5), the plating layer may include the first layer, the second layer and a fourth layer provided right on the second layer, the first layer may be an alloy layer containing zinc and copper, the second layer may include a pure metal layer made of pure nickel, and the fourth layer may be an alloy layer containing tin and copper.

The shield member of (9) exhibits effects similar to those of the shield member of (8). In the shield member of (9), the first alloy layer is formed as the first layer right on the die-cast member.

(10) In the shield member of any one of (5) to (9) described above, the thickness of the third layer may be 0.5 μm or more.

In the shield member of (10), the electrical conductivity of the shield member is easily satisfactorily ensured. In the shield member of (10), solder wettability is easily satisfactorily ensured.

### DETAILS OF EMBODIMENT OF PRESENT DISCLOSURE

Specific examples of embodiments of the present disclosure are described below with reference to the drawings. In figures, the same reference signs denote the same components. For the convenience of description, some components may be shown in an exaggerated or simplified manner in each drawing. A dimension ratio of each part may be different in each figure. Note that the present invention is not limited to these illustrations, but is represented by claims and intended to include all changes in the scope of claims and in the meaning and scope of equivalents.

### <Summary of Shield Member>

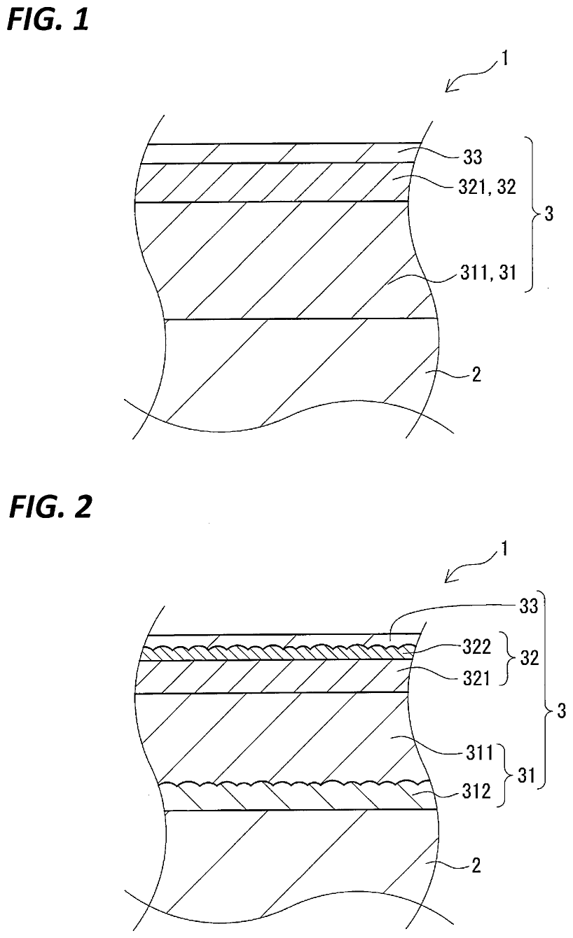

A shield member 1 of one embodiment is a member used as a part of a high frequency connector. One of features of the shield member 1 of this embodiment is that a predetermined plating layer 3 is provided on a die-cast member 2 containing zinc as shown in FIGS. 1 to 6. The shape and form of use of the shield member 1 are first described below and, thereafter, the die-cast member 2 and the plating layer 3 constituting the shield member 1 are described in detail with reference to FIGS. 1 to 6. In FIGS. 1 to 6, the plating layer 3 of the shield member 1 and the vicinity of the plating layer 3 are enlargedly and schematically shown.

### <Shape of Shield Member>

The shield member 1 is incorporated as a part of the high frequency connector. The high frequency connector is connected to an end of a shielded cable. A known configuration can be utilized as a basic configuration of the high frequency connector. The high frequency connector is provided with a plurality of terminals. Each terminal is, for example, an L-shaped rod-like piece. The shield member 1 is shaped and sized to be able to cover the plurality of terminals. The shield member 1 covers, for example, the plurality of terminals substantially entirely. A dielectric member is arranged on the outer periphery of each terminal. Electrical insulation between the respective terminals and electrical insulation between the respective terminals and the shield member 1 are ensured by the respective dielectric members.

The high frequency connector is further provided with a housing. The housing is, for example, connected to the rear end of the shield member 1. A first end part of the terminal extends to the inside of the housing and is connected to a conductor of the shielded cable inside the housing. A wall portion of the shield member 1 facing the housing, i.e. a rear wall portion in this embodiment, is provided with a plurality of holes, through which the first end parts of the respective terminals are passed. A second end part of the terminal is connected to a circuit board. A wall portion of the shield member 1 facing the circuit board, i.e. a lower wall portion in this embodiment, is provided with a plurality of holes, through which the second end parts of the respective terminals are passed.

A main part of the shield member 1 is constituted by the die-cast member 2 shown in FIGS. 1 to 6. The die-cast member 2 is fabricated by cooling a metal in a molten state, i.e. a molten metal, after the molten metal is poured under pressure into a mold. The die-cast member 2 is highly accurately fabricated even if having a complicated shape.

### <Form of Use of Shield Member>

The shield member 1 is exposed under a high temperature. The high temperature is, for example, 60° C. or higher and 260° C. or lower. For example, the shield member 1 is exposed under a high temperature when the terminals of the high frequency connector are reflow-soldered to the circuit board. At the time of reflow soldering, the shield member 1 is, for example, exposed under a high temperature of 100° C. or higher and 260° C. or lower. Besides, the shield member 1 is possibly exposed under a high temperature due to heat load in a use environment such as an engine when the high frequency connector is installed in an automotive vehicle. The high frequency connector is, for example, used in wired high speed communication in the automotive vehicle. When the high frequency connector is installed in the automotive vehicle, the shield member 1 is, for example, exposed under a temperature of 60° C. or higher and 130° C. or lower.

### <Die-Cast Member>

The die-cast member 2 constitutes the main part of the shield member 1. The shield member 1 is formed by the die-cast member 2.

The die-cast member 2 is made of pure zinc or zinc alloy. The die-cast member 2 containing zinc is high in electrical conductivity. In zinc alloy, the most contained element is zinc (Zn), out of elements constituting the alloy. The zinc alloy contains at least one type of element selected from a group consisting of aluminum (Al), magnesium (Mg), iron (Fe), lead (pb), cadmium (Cd) and tin (Sn) besides zinc. The die-cast member 2 of this example is made of zinc alloy containing aluminum and magnesium.

### <Plating Layer>

The plating layer 3 is provided on a surface of the die-cast member 2 as shown in FIGS. 1 to 6. The plating layer 3 is provided to enhance the electrical conductivity of the shield member 1. The plating layer 3 is different in a state immediately after plating and a state after being exposed under a high temperature.

### First Embodiment

A plating layer 3 of a first embodiment is described with reference to FIG. 1. A state of the plating layer 3 of the first embodiment is a state before being exposed under a high temperature. The plating layer 3 of the first embodiment is provided with a third layer 33 provided in the outermost surface of the plating layer 3. The plating layer 3 may be provided with at least one of a first layer 31 and a second layer 32. The plating layer 3 of the first embodiment includes the first layer 31, the second layer 32 and the third layer 33 provided in this order from a position near the die-cast member 2. Each of the first, second and third layers 31, 32 and 33 is constituted by a pure metal layer.

### [First Layer]

The first layer 31 is a first pure metal layer 311 made of pure copper. In pure copper, a content of copper (Cu) is 99.95% by mass or more. The first layer 31 is provided at a position closest to the die-cast member 2 in the plating layer 3, i.e. right on the die-cast member 23. The first layer 31 is a base layer for providing the later-described third layer 33 on the die-cast member 2.

A thickness of the first layer 31 is, for example, 10 μm or more and 15 μm or less. By setting the thickness of the first layer 31 to 10 μm or more, the third layer 33 is reliably provided as the plating layer 3. By setting the thickness of the first layer 31 to 15 μm or less, a thickness increase of the plating layer 3 is suppressed. By setting the thickness of the first layer 31 to 15 μm or less, an increase in time is suppressed in forming the plating layer 3. The thickness of the first layer 31 may be 12 μm or more and 15 μm or less. The thickness of the first layer 31 can be measured, using a fluorescent X-ray thickness meter. The thickness of the first layer 31 is an average value of thicknesses measured at a plurality of different measurement points in the first layer 31. The number of the measurement points is ten points or more, twenty points or more or thirty points or more.

### [Second Layer]

The second layer 32 is a second pure metal layer 321 made of pure nickel. In pure nickel, a content of nickel (Ni) is 99.99% by mass or more. The second layer 32 is provided right on the first layer 31. The second layer 32 is provided to suppress the diffusion of copper contained in the first layer 31 toward the third layer 33.

A thickness of the second layer 32 is, for example, 2 μm or more and 5 μm or less. By setting the thickness of the second layer 32 to 2 μm or more, the diffusion of copper contained in the first layer 31 toward the first layer 31 is easily suppressed. By setting the thickness of the second layer 32 to 5 μm or less, a thickness increase of the plating layer 3 is suppressed. By setting the thickness of the second layer 32 to 5 μm or less, an increase in time is suppressed in forming the plating layer 3. The thickness of the second layer 32 may be 4 μm or more and 5 μm or less. Similarly to the first layer 31, the thickness of the second layer 32 can be measured, using a fluorescent X-ray thickness meter. Similarly to the first layer 31, the thickness of the second layer 32 is an average value of thicknesses measured at a plurality of different measurement points in the second layer 32.

### [Third Layer]

The third layer 33 is a pure metal layer made of pure tin. In pure tin, a content of tin (Sn) is 99.99% by mass or more. The third layer 33 constitutes the outermost surface of the plating layer 3. The third layer 33 is provided to enhance the electrical conductivity of the shield member 1.

A thickness of the third layer 33 is less than 5 μm. By setting the thickness of the third layer 33 to less than 5 μm, it can be suppressed that the plating layer 3 is swollen or peeled under a high temperature as described in Test Examples later. The thickness of the third layer 33 may be 4 μm or less. The thickness of the third layer 33 is, for example, 1 μm or more. By setting the thickness of the third layer 33 to 1 μm or more, the electrical conductivity of the shield member 1 is easily satisfactorily ensured. By setting the thickness of the third layer 33 to 1 μm or more, solder wettability is easily satisfactorily ensured. The thickness of the third layer 33 is more than 0 μm and less than 5 μm, 1 μm or more and less than 5 μm, 2 μm or more and 4 μm or less, or 2 μm or more and 3 μm or less. Similarly to the first layer 31, the thickness of the third layer 33 can be measured, using a fluorescent X-ray thickness meter. Similarly to the first layer 31, the thickness of the third layer 33 is an average value of thicknesses measured at a plurality of different measurement points in the third layer 33.

The plating layer 3 may include only the third layer 33. The plating layer 3 may include the first layer 31 and the third layer 33, but may not include the second layer 32. The plating layer 3 may include the second layer 32 and the third layer 33, but may not include the first layer 31.

### Second Embodiment

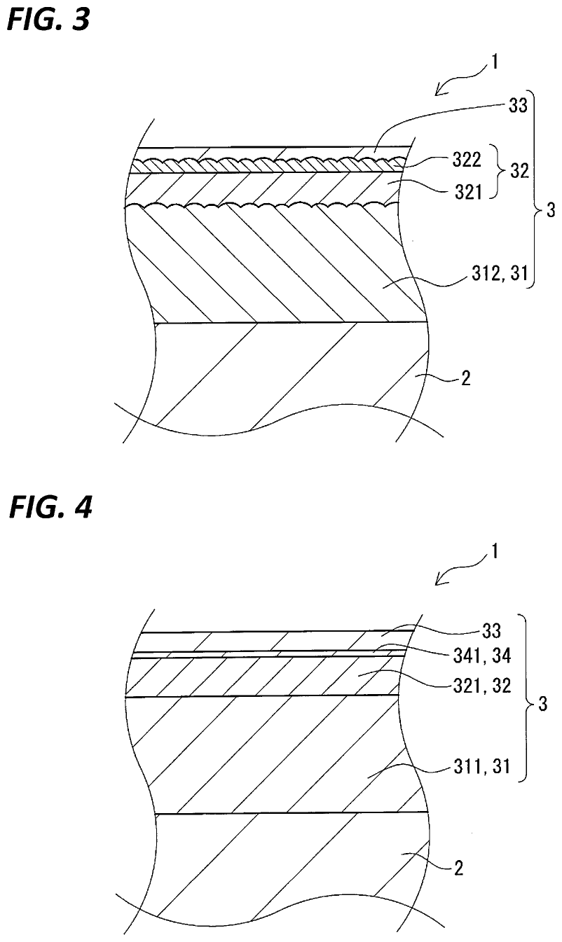

A plating layer 3 of a second embodiment is described with reference to FIGS. 2 and 3. A state of the plating layer 3 of the second embodiment is a state after a shield member 1 including the plating layer 3 of the first embodiment is exposed under a high temperature. The plating layer 3 of the second embodiment includes at least one of a first layer 31, a second layer 32 and a third layer 33. The plating layer 3 of the second embodiment includes the first layer 31, the second layer 32 and the third layer 33 provided in this order from a position near a die-cast member 2. The plating layer 3 of the second embodiment differs from the plating layer 3 of the first embodiment in that the first layer 31 includes a first alloy layer 312 and the second layer 32 includes a second alloy layer 322. As shown in FIG. 2, the first layer 31 may further include a first pure metal layer 311. In the plating layer 3 shown in FIG. 3, the first layer 31 is constituted by the first alloy layer 312. FIGS. 2 and 3 differ in that the first layer 31 includes the first pure metal layer 311 or not.

### [First Layer]

The first layer 31 includes the first alloy layer 312 provided right on the die-cast member 2. The first alloy layer 312 contains zinc and copper. The first alloy layer 312 is a layer formed by alloying zinc contained in the die-cast member 2 and copper contained in the first layer 31 in the plating layer 3 of the first embodiment under a high temperature. The first pure metal layer 311 shown in FIG. 2 is provided as the first layer 31 depending on the thickness of the first layer 31 in the plating layer 3 of the first embodiment and conditions under a high temperature. The first pure metal layer 311 is made of pure copper. The first pure metal layer 311 is a layer of remaining copper contained in the first layer 31 in the plating layer 3 of the first embodiment without being alloyed. The first pure metal layer 311 is provided right on the first alloy layer 312.

The first alloy layer 312 becomes thicker and the first pure metal layer 311 becomes relatively thinner as the temperature under the high temperature increases or a holding time under the high temperature becomes longer. Depending on the conditions under the high temperature, the entire first layer 31 in the plating layer 3 of the first embodiment possibly becomes the first alloy layer 312 as shown in FIG. 3.

If the first alloy layer 312 and the first pure metal layer 311 are provided as in the first layer 31 shown in FIG. 2, a thickness of the first alloy layer 312 is, for example, 0.5 μm or more and 2 μm or less. The thinner the first alloy layer 312, the better. The thickness of the first alloy layer 312 is, for example, 0.5 μm or more and 1 μm or less.

A thickness of the first pure metal layer 311 is, for example, 5 μm or more and 15 μm or less. By setting the thickness of the first pure metal layer 311 to 5 μm or more, the diffusion of zinc to the second layer 32 is easily suppressed. By setting the thickness of the first pure metal layer 311 to 15 μm or less, a thickness increase of the plating layer 3 is suppressed. The thickness of the first pure metal layer 311 may be 10 μm or more and 15 μm or less.

If the first layer 31 is constituted by the first alloy layer 312 like the first layer 31 shown in FIG. 3, the thickness of the first alloy layer 312 is, for example, 10 μm or more and 15 μm or less.

If the first alloy layer 312 and the first pure metal layer 311 are provided like the first layer 31 shown in FIG. 2, the thickness of each of the first alloy layer 312 and the first pure metal layer 311 can be measured as follows, using a scanning electron microscope. First, an arbitrary cross-section along a lamination direction of the die-cast member 2 and the plating layer 3 in the shield member 1 is taken. The number of the cross-sections may be one or more. A plurality of backscattered electron images are obtained from one or more cross-sections. If there is one cross-section, a plurality of backscattered electron images are obtained from that cross-section. If there are a plurality of cross-sections, one or more backscattered electron images are obtained from each cross-section. A total number of the backscattered electron images is, for example, three. In each backscattered electron image, the thickness of the first alloy layer 312 or the first pure metal layer 311 in the first layer 31 is measured. The thickness of the first alloy layer 312 is an average value of thicknesses measured at a plurality of different measurement points in the first alloy layer 312. The thickness of the first pure metal layer 311 is an average value of thicknesses measured at a plurality of different measurement points in the first pure metal layer 311. The number of the measurement points is ten points or more, twenty points or more or thirty points or more.

### [Second Layer]

The second layer 32 includes a second alloy layer 322 and a second pure metal layer 321 as shown in FIGS. 2 and 3.

The second alloy layer 322 is provided right below the third layer 33. The second alloy layer 322 contains tin and nickel. The second alloy layer 322 is a layer formed by alloying nickel contained in the second layer 32 and tin contained in the third layer 33 in the plating layer 3 of the first embodiment under a high temperature. Even if being exposed to a high temperature, the second layer 32 in the plating layer 3 of the first embodiment is not entirely alloyed. In other words, the second layer 32 of the second embodiment inevitably includes the second pure metal layer 321. The second pure metal layer 321 is made of pure nickel. The second pure metal layer 321 is provided right below the second alloy layer 322. The second pure metal layer 321 is provided right on the first layer 31, and the second alloy layer 322 is provided right on the second pure metal layer 321.

A thickness of the second alloy layer 322 is, for example, 0.5 μm or more and 1.5 μm or less. By setting the thickness of the second alloy layer 322 to 0.5 μm or more, further diffusion of tin to the second pure metal layer 321 is easily suppressed. By setting the thickness of the second alloy layer 322 to 1.5 μm or less, the thickness of the third layer 33 satisfies a specific range. The thinner the second alloy layer 322, the better. The thickness of the second alloy layer 322 is, for example, 0.5 μm or more and 1 μm or less.

A thickness of the second pure metal layer 321 is, for example, 1 μm or more and 5 μm or less. By setting the thickness of the second pure metal layer 321 to 1 μm or more, the diffusion of zinc and copper contained in the first layer 31 to the third layer 33 is easily suppressed. By setting the thickness of the second pure metal layer 321 to 1 μm or more, the thickness of the third layer 33 satisfies the specific range. By setting the thickness of the second pure metal layer 321 to 5 μm or less, a thickness increase of the second layer 32 is suppressed. The thickness of the second pure metal layer 321 may be 2 μm or more and 5 μm or less.

Similarly to the first alloy layer 312 and the first pure metal layer 311, each of the second alloy layer 322 and the second pure metal layer 321 can be can be measured as follows, using a scanning electron microscope. Similarly to the first alloy layer 312, the thickness of the second alloy layer 322 is an average value of thicknesses measured at a plurality of different measurement points in the second alloy layer 322. Similarly to the first pure metal layer 311, the thickness of the second pure metal layer 321 is an average value of thicknesses measured at a plurality of different measurement points in the second pure metal layer 321.

### [Third Layer]

The third layer 33 is a pure metal layer made of pure tin.

A thickness of the third layer 33 is less than 3 μm. By setting the thickness of the third layer 33 to less than 3 μm, it can be suppressed that the plating layer 3 is swollen or peeled under a high temperature as described in Test Examples later. This third layer 33 is thinner than the third layer 33 in the plating layer 3 of the first embodiment. This third layer 33 is thinner because nickel contained in the second layer 32 and tin contained in the third layer 33 in the plating layer 3 of the first embodiment are alloyed under a high temperature as described above. The third layer 33 in the plating layer 3 of the first embodiment may have a thickness of 0 μm when being exposed under a high temperature. That is, the thickness of the third layer 33 after being exposed under a high temperature is 0 μm or more and less than 3 μm. The thickness of the third layer 33 may be 0.5 μm or more and less than 3 μm. Similarly to the third layer 33 of the first embodiment, the thickness of the third layer 33 can be measured, using a fluorescent X-ray thickness meter. Similarly to the third layer 33 of the first embodiment, the thickness of the third layer 33 is an average value of thicknesses measured at a plurality of different measurement points in the third layer 33.

### Third Embodiment

A plating layer 3 of a third embodiment is described with reference to FIG. 4. The plating layer 3 of the third embodiment includes a first layer 31, a second layer 32, a third layer 33 and a fourth layer 34. The fourth layer 34 is provided between the second and third layers 32, 33. A state of the plating layer 3 of the third embodiment is a state before being exposed under a high temperature. Each of the first, second, third and fourth layers 31, 32, 33 and 34 is constituted by a pure metal layer. The plating layer 3 of the third embodiment differs from the plating layer 3 of the first embodiment in including the fourth layer 34. The configurations of the first, second and third layers 31, 32 and 33 in the plating layer 3 of the third embodiment are similar to those of the first embodiment. The fourth layer 34 is described below.

### [Fourth Layer]

The fourth layer 34 is a fourth pure metal layer 341 made of pure copper. The fourth layer 34 is provided between the second and third layers 32, 33. The fourth layer 34 is provided right below the third layer 33. The fourth layer 34 is provided to suppress the diffusion of nickel contained in the second layer 32 toward the third layer 33. Copper and tin are easily alloyed, but copper is less alloyed with tin than nickel.

A thickness of the fourth layer 34 is, for example, 0.1 μm and more and 0.4 μm or less. By setting the thickness of the fourth layer 34 to 0.1 μm and more, copper contained in the fourth layer 34 and tin contained in the third layer 33 are alloyed at the time of a reflow process. By this alloying, the diffusion of nickel contained in the second layer 32 toward the third layer 33 is easily suppressed. By setting the thickness of the fourth layer 34 to 0.4 μm or less, it is suppressed that copper contained in the fourth layer 34 and tin contained in the third layer 33 are excessively alloyed. The thickness of the fourth layer 34 may be 0.2 μm and more and 0.3 μm or less. Similarly to the first alloy layer 312 and the first pure metal layer 311 in the second embodiment, the thickness of the fourth layer 34 can be can be measured, using a scanning electron microscope. The thickness of the fourth layer 34 is an average value of thicknesses measured at a plurality of different measurement points in the fourth layer 34.

### Fourth Embodiment

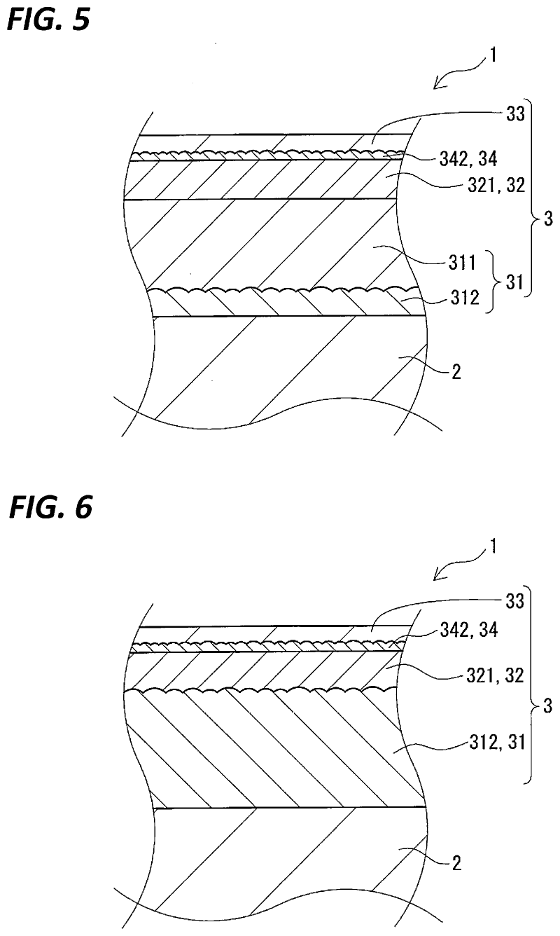

A plating layer 3 of a fourth embodiment is described with reference to FIGS. 5 and 6. A state of the plating layer 3 of the fourth embodiment is a state after a shield member 1 provided with the plating layer 3 of the third embodiment is exposed under a high temperature. The plating layer 3 of the fourth embodiment includes a first layer 31, a second layer 32, a third layer 33 and a fourth layer 34. The plating layer 3 of the fourth embodiment differs from the plating layer 3 of the third embodiment in that the first layer 31 includes a first alloy layer 312 and the fourth layer 34 is constituted by a fourth alloy layer 342. As shown in FIG. 5, the first layer 31 may further include a first pure metal layer 311. In the plating layer 3 shown in FIG. 6, the first layer 31 is constituted by the first alloy layer 312. FIGS. 5 and 6 differ in that the first layer 31 includes the first pure metal layer 311 or not. The plating layer 3 of the fourth embodiment can also be fabricated by intentionally applying a heat treatment to the shield member 1 provided with the plating layer 3 of the third embodiment.

### [First Layer]

The first layer 31 includes the first alloy layer 312 provided right on a die-cast member 2. The first alloy layer 312 contains zinc and copper. The first alloy layer 312 is a layer formed by alloying zinc contained in the die-cast member 2 and copper contained in the first layer 31 in the plating layer 3 of the third embodiment under a high temperature. The first pure metal layer 311 shown in FIG. 5 is provided as the first layer 31 depending on the thickness of the first layer 31 in the plating layer 3 of the third embodiment and conditions under a high temperature. The first pure metal layer 311 is made of pure copper. The first pure metal layer 311 is a layer of remaining copper contained in the first layer 31 in the plating layer 3 of the third embodiment without being alloyed. The first pure metal layer 311 is provided right on the first alloy layer 312. The first alloy layer 312 becomes thicker and the first pure metal layer 311 becomes relatively thinner as the temperature under the high temperature increases or a holding time under the high temperature becomes longer. Depending on the conditions under the high temperature, the entire first layer 31 in the plating layer 3 of the third embodiment possibly becomes the first alloy layer 312 as shown in FIG. 6. The configuration of the first layer 31 in the plating layer 3 of the fourth embodiment is similar to that of the second embodiment.

### [Second Layer]

The second layer 32 includes a second pure metal layer 321 as shown in FIGS. 5 and 6. The second layer 32 may include an unillustrated second alloy layer. The second alloy layer is provided right on the second pure metal layer 321.

A thickness of the second pure metal layer 321 is, for example, 2 μm or more and 5 μm or less. By setting the thickness of the second pure metal layer 321 to 2 μm or more, the diffusion of zinc and copper contained in the first layer 31 to the third layer 33 is easily suppressed. By setting the thickness of the second pure metal layer 321 to 5 μm or less, the thickness of the third layer 33 satisfies the specific range. The thickness of the second pure metal layer 321 is preferably 4 μm or more and 5 μm or less.

The unillustrated second alloy layer contains tin, copper and nickel. The second alloy layer is a layer formed by alloying tin contained in the third layer 33, copper contained in the fourth layer 34 and nickel contained in the second layer 32 in the plating layer 3 of the third embodiment under a high temperature. Even if being exposed under a high temperature, the second layer 32 in the plating layer 3 of the third embodiment is not entirely alloyed. A thickness of the second alloy layer is, for example, 5 μm or less.

### [Fourth Layer]

The fourth layer 34 is provided between the second and third layers 32, 33. The fourth layer 34 is provided right below the third layer 33. The fourth layer 34 is the fourth alloy layer 342 containing tin and copper. The fourth layer 34 is a layer formed by alloying copper contained in the fourth layer 34 and tin contained in the third layer 33 in the plating layer 3 of the third embodiment under a high temperature. If being exposed under a high temperature, the fourth layer 34 in the plating layer 3 of the third embodiment is entirely alloyed.

A thickness of the fourth layer 34 is, for example, 0.1 μm and more and 0.4 μm or less. By setting the thickness of the fourth layer 34 to 0.1 μm and more, the diffusion of nickel contained in the second layer 32 toward the third layer 33 is easily suppressed. By setting the thickness of the fourth layer 34 to 0.4 μm or less, a thickness increase of the plating layer 3 is suppressed. The thickness of the fourth layer 34 is, for example, 0.2 μm and more and 0.3 μm or less. Similarly to the fourth layer 34 in the third embodiment, the thickness of the fourth layer 34 can be measured, using a scanning electron microscope. The thickness of the fourth layer 34 is an average value of thicknesses measured at a plurality of different measurement points in the fourth layer 34.

### [Third Layer]

The third layer 33 is a pure metal layer made of pure tin.

A thickness of the third layer 33 is less than 3 km. By setting the thickness of the third layer 33 to less than 3 μm, it can be suppressed that the plating layer 3 is swollen or peeled under a high temperature as described in Test Examples later. This third layer 33 is thinner than the third layer 33 in the plating layer 3 of the third embodiment. This third layer 33 is thinner because copper contained in the fourth layer 34 and tin contained in the third layer 33 in the plating layer 3 of the third embodiment are alloyed under a high temperature as described above. The third layer 33 in the plating layer 3 of the third embodiment may have a thickness of 0 μm when being exposed under a high temperature. That is, the thickness of the third layer 33 after being exposed under a high temperature is 0 μm or more and less than 3 μm. The thickness of the third layer 33 may be 0.5 μm or more and less than 3 μm, 1 μm or more and less than 3 μm or 2 μm or more and less than 3 μm. Similarly to the third layer 33 of the first embodiment, the thickness of the third layer 33 can be measured, using a fluorescent X-ray thickness meter. Similarly to the third layer 33 of the first embodiment, the thickness of the third layer 33 is an average value of thicknesses measured at a plurality of different measurement points in the third layer 33.

### Test Example 1

In Test Example 1, shield members each including a plating layer on a die-cast member containing zinc were fabricated. States of the plating layers after these shield members were exposed under a high temperature were examined.

### <Samples>

The die-cast members of a predetermined shape were prepared. The die-cast member is made of zinc alloy containing aluminum and magnesium. A first layer, a second layer and a third layer were plated on the die-cast member in this order from a position near the die-cast member. The first layer is made of pure copper. The second layer is made of pure nickel. The third layer is made of pure tin. A thickness of each of the first, second and third layers is shown in Table 1. If “0” is written in a cell of Table 1, it indicates that the layer corresponding to that cell is not formed.

TABLE 1

| | Thickness of Plating Layer Immediately After Plating (μm) | | |
|---|---|---|---|
| Sample No. | 1^{st} Layer | 2^{nd} Layer | 3^{rd} Layer |
| 1-1 | 15 | 0 | 1 |
| 1-2 | 5 | 1 | 1 |
| 1-3 | 0 | 5 | 1 |
| 1-4 | 15 | 1 | 5 |
| 1-5 | 5 | 5 | 5 |
| 1-6 | 0 | 0 | 5 |
| 1-7 | 15 | 5 | 10 |
| 1-8 | 5 | 0 | 10 |
| 1-9 | 0 | 1 | 10 |

The shield members formed with the plating layers shown in Table 1 on the die-cast members were left under a high temperature of 125° C. for 120 hours. It is assumed that Samples Nos. 1-1 to 1-9 shown in Table 1 after being left under a high temperature are successively Samples Nos. 1-11 to 1-19.

### <Plating Layers>

States of the plating layers in Samples Nos. 1-11 to 1-19 were examined. As a result, in Sample including the first layer before being left under a high temperature, a first alloy layer was formed as the first layer right on the die-cast member. The first alloy layer contained zinc and copper. Depending on Samples, a first pure metal layer was formed as the first layer right on the first alloy layer. The first pure metal layer is made of pure copper. Out of Samples including the second layer before being left under a high temperature, a second alloy layer was formed as the second layer right below the third layer and a second pure metal layer was formed right below the second alloy layer in Samples Nos. 1-13, 1-15 and 1-17. The second alloy layer contained tin and nickel. The second pure metal layer is made of pure nickel. In Sample including the third layer, the third layer is made of pure tin. A thickness of each layer is shown in Table 2. If “0” is written in a cell of Table 2, it indicates that the layer corresponding to that cell is absent.

### <Surface Observation>

Surfaces of the plating layers in Samples Nos. 1-11 to 1-19 were visually observed. A result is shown in Table 2. A in Table 2 indicates that the plating layer was properly provided without being swollen or peeled. B in Table 2 indicates that the plating layer was swollen or peeled.

TABLE 2

| | Thickness of Plating Layer after being Left under | | | | | |
|---|---|---|---|---|---|---|
| | High Temperature (μm) | | | | | |
| | 1^{st} Layer | | 2^{nd} Layer | | | Surface |
| Sample | 1^{st} Alloy | 1^{st} Pure | 2^{nd} Alloy | 2^{nd} Pure | | Observation |
| No. | Layer | Metal Layer | Layer | Metal Layer | 3^{rd} Layer | Result |
| 1-11 | 5 | 10 | 0 | 0 | 0 | A |
| 1-12 | 1 | 4 | 1 | 0 | 0 | A |
| 1-13 | 0 | 0 | 2 | 3 | 0 | A |
| 1-14 | 5 | 10 | 1 | 0 | 4 | B |
| 1-15 | 5 | 0 | 2 | 3 | 3 | B |
| 1-16 | 0 | 0 | 0 | 0 | 3 | B |
| 1-17 | 5 | 10 | 2 | 3 | 8 | B |
| 1-18 | 4 | 0 | 0 | 0 | 8 | B |
| 1-19 | 0 | 0 | 1 | 0 | 9 | B |

As shown in Table 1 and Table 2, in Samples Nos. 1-1, 1-2 and 1-3 in which the thickness of the third layer immediately after plating was less than 5 μm, the plating layer was neither swollen nor peeled. On the other hand, in Samples Nos. 1-4 to 1-9 in which the thickness of the third layer immediately after plating was 5 μm or more, the plating layer was swollen or peeled after being left under a high temperature. It is thought that tin contained in the third layer was melted, agglomerated and was solidified by a high temperature and the plating layer was swollen if the third layer before being exposed under a high temperature was thick. Further, it is thought that voids were created between the die-cast member and the first alloy layer and the plating layer was peeled when the first alloy layer is formed right on the die-cast member since die-cast member contained zinc.

### Test Example 2

In Test Example 2, shield members each including a plating layer different from those in Test Example 1 on a die-cast member containing zinc were fabricated. States of the plating layers after these shield members were exposed under a high temperature were examined.

### <Samples>

The die-cast members of a predetermined shape were prepared. The die-cast member is made of zinc alloy containing aluminum and magnesium. A first layer, a second layer, a fourth layer and a third layer were plated on the die-cast member in this order from a position near the die-cast member. The first and fourth layers are made of pure copper. The second layer is made of pure nickel. The third layer is made of pure tin. A thickness of each of the first, second, third and fourth layers is shown in Table 3. If “0” is written in a cell of Table 3, it indicates that the layer corresponding to that cell is not formed.

TABLE 3

| | Thickness of Plating Layer Immediately After Plating (μm) | | | |
|---|---|---|---|---|
| Sample No. | 1^{st} Layer | 2^{nd} Layer | 3^{rd} Layer | 4^{th} Layer |
| 2-1 | 10 | 5 | 4 | 0 |
| 2-2 | 10 | 5 | 3 | 0 |
| 2-3 | 10 | 5 | 3 | 0.3 |
| 2-4 | 10 | 5 | 2 | 0 |
| 2-5 | 10 | 5 | 2 | 0.3 |
| 2-6 | 10 | 5 | 1 | 0 |
| 2-7 | 10 | 5 | 1 | 0.3 |

The shield members formed with the plating layers shown in Table 3 on the die-cast members were left under a high temperature of 125° C. for 120 hours. It is assumed that Samples Nos. 2-1 to 2-7 shown in Table 3 after being left under a high temperature are successively Samples Nos. 2-11 to 2-17.

### <Plating Layers>

States of the plating layers in the shield members after being left under a high temperature were examined. As a result, the first and fourth layers were formed with alloy layers as described below. A first alloy layer was formed as the first layer right on the die-cast member. The first alloy layer contained zinc and copper. A first pure metal layer was formed as the first layer right on the first alloy layer. The first pure metal layer was made of pure copper. A second pure metal layer was formed as the second layer. The second pure metal layer was made of pure nickel. A second alloy layer was formed as the second layer right on the second pure metal layer. The second alloy layer contained tin, copper and nickel. In Sample including the third layer, the third layer was made of pure tin. An alloy layer containing tin and copper was formed as the fourth layer. If “0” is written as the thickness of the layer in a cell of Table 4, it indicates that the layer corresponding to that cell is absent.

### <Surface Observation>

Surfaces of the plating layers in the shield members after being left under a high temperature were visually observed. A result is shown in Table 4. A in Table 4 indicates that the plating layer was properly provided without being swollen or peeled. B in Table 4 indicates that the plating layer was swollen or peeled.

TABLE 4

| | Thickness of Plating Layer after being Left under | | | | | | |
|---|---|---|---|---|---|---|---|
| | High Temperature (μm) | | | | | | |
| | 1^{st} Layer | | 2^{nd} Layer | | | | |
| | | 1^{st} Pure | | 2^{nd} Pure | | | Surface |
| Sample | 1^{st} Alloy | Metal | 2^{nd} Alloy | Metal | | | Observation |
| No. | Layer | Layer | Layer | Layer | 3^{rd} Layer | 4^{th} Layer | Result |
| 2-11 | 5 | 5 | 1 | 4 | 2 | 0 | A |
| 2-12 | 5 | 5 | 1 | 4 | 1 | 0 | A |
| 2-13 | 5 | 5 | 1 | 4 | 2 | 0.3 | A |
| 2-14 | 5 | 5 | 1 | 4 | 0 | 0 | A |
| 2-15 | 5 | 5 | 1 | 4 | 1 | 0.3 | A |
| 2-16 | 5 | 5 | 1 | 4 | 0 | 0 | A |
| 2-17 | 5 | 5 | 1 | 4 | 0.5 | 0.3 | A |

As shown in Table 3 and Table 4, since the thickness of the third layer immediately after plating was less than 5 μm in any of Samples, the plating layer was neither swollen nor peeled. Particularly, Samples Nos. 2-3, 2-5 and 2-7 provided with the fourth layer included the third layer after being left under a high temperature even if the third layer immediately after plating was as thin as 3 μm or less. It is thought that the alloying of nickel in the second layer and tin in the third layer was suppressed by including the fourth layer.

### LIST OF REFERENCE NUMERALS

1 shield member
2 die-cast member
3 plating layer
31 first layer
311 first pure metal layer, 312 first alloy layer
32 second layer
321 second pure metal layer, 322 second alloy layer
33 third layer
34 fourth layer
341 fourth pure metal layer, 342 fourth alloy layer

1. A shield member, comprising:
a die-cast member; and
a plating layer provided on a surface of the die-cast member,
the die-cast member containing zinc,
the plating layer including a third layer provided in an outermost surface of the plating layer,
the third layer being made of pure tin, and
a thickness of the third layer being less than 5 μm.

2. The shield member of claim 1, wherein:
the plating layer includes at least one of a first layer and a second layer,
the first layer, the second layer and the third layer are provided in this order from a position near the die-cast member,
the first layer is made of pure copper, and
the second layer is made of pure nickel.

3. The shield member of claim 2, wherein:
the plating layer includes the second layer and a fourth layer provided between the second layer and the third layer, and
the fourth layer is made of pure copper.

4. The shield member of claim 1,
wherein a thickness of the third layer is 1 μm or more.

5. A shield member, comprising:
a die-cast member; and
a plating layer provided on a surface of the die-cast member,
the die-cast member containing zinc,
the plating layer including at least one of a first layer, a second layer and a third layer,
the first layer, the second layer and the third layer being provided in this order from a position near the die-cast member,
the first layer containing copper,
the second layer containing nickel,
the third layer being made of pure tin, and
a thickness of the third layer being 0 μm or more and less than 3 μm.

6. The shield member of claim 5, wherein:
the plating layer includes the first layer and the second layer,
the first layer includes:
a first alloy layer containing zinc and copper; and
a first pure metal layer made of pure copper,
the first alloy layer is provided right on the die-cast member,
the first pure metal layer is provided right on the first alloy layer,
the second layer includes:
a second alloy layer containing tin and nickel; and
a second pure metal layer made of pure nickel,
the second pure metal layer is provided right on the first pure metal layer, and
the second alloy layer is provided right on the second pure metal layer.

7. The shield member of claim 5, wherein:
the plating layer includes the first layer and the second layer,
the first layer is an alloy layer containing zinc and copper,
the second layer includes:
a second alloy layer containing tin and nickel; and
a second pure metal layer made of pure nickel,
the second pure metal layer is provided right on the first layer, and
the second alloy layer is provided right on the second pure metal layer.

8. The shield member of claim 5, wherein:
the plating layer includes the first layer, the second layer and a fourth layer provided right on the second layer,
the first layer includes:
a first alloy layer containing zinc and copper; and
a first pure metal layer made of pure copper,
the first alloy layer is provided right on the die-cast member,
the first pure metal layer is provided right on the first alloy layer,
the second layer includes a pure metal layer made of pure nickel, and
the fourth layer is an alloy layer containing tin and copper.

9. The shield member of claim 5, wherein:
the plating layer includes the first layer, the second layer and a fourth layer provided right on the second layer,
the first layer is an alloy layer containing zinc and copper,
the second layer includes a pure metal layer made of pure nickel, and
the fourth layer is an alloy layer containing tin and copper.

10. The shield member of claim 5, wherein the thickness of the third layer is 0.5 μm or more.
